(19) United States
(12) Patent Application Publication
(10) Pub. No.: US 2005/0151253 A1
(43) Pub. Date: Jul. 14, 2005

(54) Bonding wire and an integrated circuit device using the same

(75) Inventors: Tsuyoshi Nonaka, Kouka-gun (JP); Masanori Ioka, Kouka-gun (JP); Shingo Kaimori, Osaka-shi (JP); Masato Fukagaya, Nagoya Aichi (JP)

Correspondence Address: McDermott Will & Emery, 600 13th Street N W, Washington, DC, 20005-3096, US

(73) Assignee: Sumitomo Electric Wintec, Incorporated, Shiga (JP)

(21) Appl. No.: 10/508,052

(22) PCT Filed: Mar. 24, 2003
(86) PCT No.: PCT/JP03/03492

(30) Foreign Application Priority Data
Mar. 26, 2002 (JP) 2002-85891

(51) Int. Cl. H01L 23/48

(52) U.S. Cl. 257/741

(57) ABSTRACT

A bonding wire comprising a core mainly consisting of copper, a different metal layer formed of a metal other than copper and formed on the core, and a coating layer formed of an oxidation-resistant metal having a melting point higher than that of copper and formed on the different metal layer, from which balls having the shape of a true sphere in a wide ball diameter range can be formed stably, which can be produced without causing the deterioration of a plating solution at the time of plating, and in which the adhesiveness between the coating layer and the core thereof is excellent; and an integrated circuit device using the bonding wire are provided.

### TECHNICAL FIELD

The present invention relates to a bonding wire for connecting electrodes on integrated circuit chips (ICs, LSIs, transistors and the like) to conductive wires on circuit wiring substrates (lead frames, ceramic substrates, printed circuit boards and the like), and also relates to an integrated circuit device using the bonding wire.

### BACKGROUND ART

As the methods of connecting integrated circuit chips to circuit wiring substrates, the ball bonding method, wedge bonding method, solder bonding method, resistance welding method and the like are used. Among these, the ball bonding method using thin gold wires is generally used.

General ball bonding method is carried out according to the following process. The tip of a bonding wire guided by a movable capillary (hereafter referred to as a “bonding tool”) is melted by electric discharge between the wire and an electrode torch, thereby forming a ball. While ultrasound is applied, the ball is pressed against an electrode on an integrated circuit chip serving as a first bonding point, thereby carrying out bonding. Thereafter, while the wire is being fed, the bonding tool is moved to an electrode on a circuit wiring substrate serving as a second bonding point, and bonding is carried out, too. (No ball is formed at this stage). After the bonding, the bonding tool is raised, and a clamp pulls the wire to cut it.

So far, gold has been used as the material for this kind of bonding wire. However, since gold is expensive, a bonding wire made of another inexpensive metal is desired to be developed.

After an integrated circuit chip is connected to circuit wires, an encapsulation is carried out for circuit protection. Resin encapsulation is widely used as a encapsulation method. In the case of the resin encapsulation, molten resin is flown to the circuit wires to cover the circuit, and then the resin is cured. At the time of the encapsulation, portions of wires may be drifted by the flow of the resin, and adjacent wires may make contact with each other, thereby causing short circuits. This problem has increased as a result of the promotion of reducing the distance between adjacent wires in the wiring of bonding wires for attaining high-density integration and size reduction of integrated circuit devices, in particular. Hence, a bonding wire having high stiffness so as not to be drifted by the flow of resin is desired.

As a bonding wire made of an inexpensive metal and having high stiffness, a bonding wire made of copper as the raw material has been developed, and Japanese Patent Publication No. 8-28382, for example, discloses such bonding wires. However, the copper bonding wire has the problems that:
since the surface of the copper bonding wire is liable to be oxidized, it is difficult to store the wire for a long period;
oxidation advances owing to heat conduction from the substrate during bonding, resulting in defective bonding; and the like.

In order to prevent the surface of the copper bonding wire from oxidation, bonding wires made of copper coated with noble metals or corrosion-resistant metals such as gold, silver, platinum, palladium, nickel, cobalt, chromium, titanium, and the like have been proposed in Japanese Laid-open Patent Publication No. 62-97360. These wires are less expensive than the gold bonding wire and it is believed that they can attain an excellent bonding characteristic without causing surface oxidation.

However, in order to further enhance the high-density integration and size reduction of integrated circuit devices, that is, in order to further reduce the distance between adjacent wires, the inventors of the present invention evaluated a copper bonding wire coated with gold or palladium and found that a new problem was caused as described below.

(1) Forming small-diameter balls is indispensable to narrow the distance between adjacent wires. However, if an attempt is made to form small-diameter balls (meaning a ball having the diameter of about 3 times the wire diameter or smaller) by using the gold-plated copper bonding wire, the balls do not have the shape of a true sphere, but have the shape of a spear, and the reproducibility of the shape is unstable, thereby causing a problem of lower bonding reliability.

(2) Unlike the copper bonding wire coated with gold, the copper bonding wire coated with palladium can form small-diameter balls, without forming balls having the shape of a spear. However, in the case when the diameter of a ball is large or even when the diameter of a ball is categorized as a small diameter but the diameter is relatively large, the center of the ball may deviate from the axis of the wire, resulting in a defect of forming balls having the shape of a golf-club. The defective fraction of this defect rises as the diameter of the ball is larger.

(3) In the case when palladium coating is formed on a core mainly consisting of copper by plating to produce a copper bonding wire coated with palladium, the copper is apt to dissolve in a palladium plating solution in the plating process, whereby the plating solution is apt to deteriorate (the plating capability decreases). As a result, the quality of the plating is reduced, whereby the frequency of replacing the plating solution increases and production cost rises.

(4) In a copper bonding wire coated with palladium, the adhesiveness between the palladium coating layer and the core is weak, whereby the palladium coating layer is apt to peel off. If the palladium coating layer peels off, the core material at the portion of the peeling is liable to be oxidized, whereby the bonding capability reduces. In addition, the flakes of the palladium coating layer clogs inside a bonding tool, whereby the bonding performance of the tool reduces. Furthermore, the dropped flakes of the palladium coating layer cause defects in integrated circuit devices. In the case when a wire is produced by passing the process of wire drawing, wire breakage is apt to occur, whereby the productivity reduces. Although the adhesiveness is better when the coating layer is formed by plating than the adhesiveness when the coating layer is formed by another method such as the chemical or physical vapor deposition methods, more improvement in the adhesiveness is desired.

As described above, many problems may occur. By solving these problems encountered in the conventional technology, the present invention is intended to provide a bonding wire
from which balls having the shape of a true sphere in a wide ball diameter range can be formed stably,
which can be produced without causing the deterioration of a plating solution at the time of plating,
and, preferably, in which the adhesiveness between the coating layer and the core thereof is excellent.

The present invention is also intended to provide an integrated circuit device using the bonding wire.

### DISCLOSURE OF THE INVENTION

In a bonding wire formed by coating a core mainly consisting of copper with an oxidation-resistant metal having a melting point higher than that of copper, the present invention is characterized in solving the above-mentioned problems of the conventional technology by providing a layer formed of a metal other than copper between the core and the layer (coating layer) formed of the oxidation-resistant metal.

In other words, the present invention is a bonding wire comprising a core mainly consisting of copper, a different metal layer formed of a metal other than copper (hereafter referred to as “different metal”) and formed on the core, and a coating layer formed of an oxidation-resistant metal having a melting point higher than that of copper and formed on the different metal layer; and an integrated circuit device using the bonding wire.

As a result of an extensive study regarding the influence of the material of the coating layer of the bonding wire having a core mainly consisting of copper on the stability of ball shape during ball formation, the inventors of the present invention have found that, in the case when a metal having a melting point higher than that of copper for the core is used as the material of the coating layer, the defect of forming balls having the shape of a spear during the formation of small-diameter balls, occurring in the case of a gold-plated copper wire, does not occur, whereby balls having the shape of a true sphere are obtained easily. In the case when the melting point of the metal of the coating layer is higher than that of copper, the metal of the coating layer is prevented from dispersing and melting into the copper wire, whereby it is speculated that the balls can hold the shape of a true sphere.

In addition, the inventors of the present invention have found that, when the coating layer is formed by plating in the production process of the bonding wire, the dissolution of copper into the plating solution is prevented by providing a different metal layer, such as a gold layer, between the core and the coating layer, whereby the plating solution is hard to deteriorate.

Furthermore, the inventors have also found that the adhesiveness between the coating layer and the core can be improved, and the balls can hold the shape of a true sphere in a wider range of ball diameters, by providing the different metal layer.

In the case when gold or the like is used as the material of the coating layer, it is difficult to obtain balls of a true sphere as described above. However, in the present invention, the balls can hold the shape of a true sphere in a wider range of ball diameters, even when a metal, such as gold, having a melting point lower than that of copper is used as the material of the different metal layer formed on the core.

The present invention has been attained on the basis of these findings.

### BEST MODE FOR CARRYING OUT THE INVENTION

The bonding wire of the present invention is characterized in that a different metal layer is provided between the core and the coating layer thereof. As defined above, the different metal is a metal other than copper. A metal having a melting point lower than that of copper may also be used as the different metal as described above.

Examples of the different metal include gold, platinum, palladium, rhenium, rhodium, ruthenium, titanium, magnesium, iron, aluminum, zirconium, chromium, nickel, silver, tin, zinc, osmium, iridium and alloys of these.

Among these different metals, gold, platinum, palladium, chromium, nickel, silver, tin, zinc and alloys of these are suited, since the different metal layer can be formed easily by plating by using these metals.

In particular, metals hardly or scarcely soluble in the plating solution for use in the formation of the coating layer are preferable. From this point of view, metals having a lower ionization tendency and tending to cause passivation are preferable. Examples of this kind of metal include gold, platinum, palladium, rhodium, ruthenium, titanium, iron, aluminum, zirconium, chromium, nickel and alloys of these.

In the present invention, although the different metal layer is further coated with the coating layer, when balls are formed, the metal of the different metal layer is exposed to oxygen owing to diffusion on the surface of the balls. Hence, a metal having high oxidation resistance is preferable as the different metal. From this point of view, gold, platinum or palladium is particularly suited as the different metal.

In the case when gold, platinum or palladium is used for the different metal layer in a copper bonding wire coated with palladium, it is possible to obtain a bonding wire excellent in the adhesiveness of the palladium coating layer. Among these metals, gold is preferable because of its lower cost.

In addition to the different metal layer formed of only one different metal, a layer containing a different metal as the main ingredient and also containing copper in a range not impairing the effect of the present invention is also taken as an example of a different metal layer.

The metal for forming the different metal layer is usually different from the metal for forming the coating layer. However, the different metal layer may partially contain the metal contained in the coating layer in a range not impairing the effect of the present invention. In addition, for example, in the case when the different metal layer is formed by strike plating and when the coating layer is formed by the ordinary plating, the metal for forming the different metal layer may be the same as the metal for forming the coating layer. A case wherein the different metal layer formed by palladium strike plating and the coating layer formed by palladium plating and a case wherein the different metal layer formed by platinum strike plating and the coating layer formed by platinum plating are taken as examples of this.

Furthermore, the different metal layer may be a layer wherein a metal contained in a small amount in the core material or in the coating layer is contained as the main ingredient.

The bonding wire of the present invention is characterized in that a metal having a melting point higher than that of copper and oxidation resistance higher than that of copper is used for the coating layer. The melting point is preferably 200° C., more preferably 300° C., higher than that of copper. Particularly, at least one kind of metals selected from palladium, platinum and nickel is preferable. The melting point of copper is 1084° C., the melting point of palladium is 1554° C., the melting point of platinum is 1772° C., and the melting point of nickel is 1455° C. In particular, palladium is preferable, since it is relatively inexpensive, suitable for plating, superior to nickel in oxidation resistance and also superior to platinum in processability (wiredrawing can be done easily).

An alloy containing two or more kinds of metals selected from palladium, platinum and nickel may also be used as the coating layer material, as a matter of course. Further, an alloy containing copper and one or more metals selected from palladium, platinum and nickel may also be used as the coating layer material, as long as the alloy has higher melting point and oxidation resistance than copper. Although the material of the coating layer mainly consists of the above-mentioned elements, an alloy containing other element(s) can be used as the material, if the melting point of the alloy is higher than that of copper.

As the bonding wire of the present invention having a different metal layer and a coating layer formed on the core, a wire wherein its elongation per unit sectional area is 0.021%/μm² or more is preferred, since it has a low fraction defective of that the center of the ball is apt to deviate from the axis of the wire during ball formation, thereby being apt to cause a problem of forming a ball having the so-called shape of golf-club. The elongation per unit sectional area is more preferably 0.024%/μm² or more and particularly preferably 0.030%/μm² or more.

The elongation per unit sectional area in accordance with the present invention is a value obtained by dividing the wire elongation rate (%) at the time when a wire of 10 cm long is pulled at a pulling speed of 20 mm/min and ruptured by the sectional area of the wire (the total area (μm²) of the core, the different metal layer and the coating layer) before the pulling.

Usually, the bonding wire is drawn to obtain a final wire diameter and then subjected to annealing (final annealing) to adjust the elongation. By carrying out annealing in the middle of the wiredrawing step after coating layer formation (referred to as intermediate annealing) in addition to the final annealing, a bonding wire having a high elongation, that is difficult to be obtained only by the final annealing, can be obtained. By adopting this intermediate annealing, a bonding wire having a high elongation per unit sectional area of 0.030%/μm² or more can be obtained.

The wire having a high elongation has some advantages, such as an improvement in the controllability of the shape of a wire loop and increase of the bonding strength for the second bonding, other than the advantage of reducing the formation of a ball having the so-called shape of golf-club. By the improvement in the controllability of the shape of a wire loop, defective contacts between adjacent wires, disconnections at the bonding portion during looping, and the like can be reduced.

Core of the bonding wire of the present invention mainly consists of copper. The core includes that consisting only of copper. However, the core material preferably contains other elements in addition to copper in the total amount of 0.001% by weight or more and 1% by weight or less, in order to obtain the high elongation characteristic. An amount of impurities of 0.01% by weight or more is more preferable.

As the impurities to be contained in the core, beryllium, tin, zinc, zirconium, silver, chromium, iron, oxygen, sulfur and hydrogen are exemplified. By setting the contained amount of impurities at a specific value or more as described above, it is possible to obtain a high elongation characteristic that is hard to be attained when the amount of impurities is small. Furthermore, even in the case when the high elongation characteristic is not specifically aimed, wire breakage during processing and the like can be reduced significantly in comparison with the case when the amount of impurities is small. However, if the amount of elements other than copper is excessive, electrical characteristics become inferior, for example, electrical resistance increases, and the balls have a crater-like surface when balls are formed. From this point of view, the total amount of elements other than copper is preferably 1% by weight or less.

The bonding wire in accordance with the present invention may have a layer other than the different metal layer and the coating layer on the core in a range not impairing the effect of the present invention. The layer other than the different metal layer and the coating layer can be formed outside the coating layer or between the core and the different metal layer or between the different metal layer and the coating layer. In addition, each of the different metal layer and the coating layer may have a plurality of layers.

The diameter of the bonding wire of the present invention is not limited in particular. In the case when small-diameter balls are aimed, the wire diameter is preferably 15 to 40 μm.

The thickness of the different metal layer is not limited in particular. Usually, the thickness is preferably 0.001 to 0.1 μm and more preferably 0.001 to 0.03 μm. A thickness of about 0.001 to 0.1 times the thickness of the coating layer is usually sufficient.

The thickness of the coating layer is not limited either in particular. A thickness of about 1 to 0.0001 times the diameter of the core is preferable, although the thickness differs depending on the diameter of the wire. The thickness is more preferably about 0.3 to 0.01 times the diameter of the core. When it is assumed that Y=(the sectional area of the coating layer divided by the sectional area of the core) in the case when the wire is cross-sectioned perpendicularly, the thickness of the coating layer is preferably a value satisfying the relationship of 0.007≦Y≦0.05 and more preferably a value satisfying the relationship of 0.01≦Y≦0.04. In the case when balls having large diameters are formed, the balls are apt to have the shape of a golf-club. However, by putting limitations as described above, balls having the shape of a true sphere can be formed, whereby the fraction defective resulting in having the shape of a golf-club can be reduced. The area ratio Y can be adjusted easily by changing the thicknesses of the layer.

As a method for forming a different metal layer and a coating layer on a core, a method for forming the different metal layer by electroplating and forming the coating layer thereon by electroplating is preferable.

In the case when the different metal layer is formed by electroplating, plating methods intended to give importance to adhesiveness, generally referred to as strike plating, flash plating and substrate plating (all of these are referred to as strike plating in this description), are preferable. The plating solutions for these plating methods generally have a low metal concentration and have conductive salt composition capable of stable plating at high potential. In particular, strike plating of gold, strike plating of nickel, strike plating of palladium, strike plating of platinum, and strike plating of these alloys are preferable.

It is economically preferable to use a method wherein a different metal is coated first on a thick copper wire by plating or strike plating, and a metal, that is, the material of the coating layer, is coated by thick plating, and then the wire thus obtained is drawn several times so as to have a desired wire diameter and desired layer thicknesses. In particular, the combination of electroplating and wire drawing is excellent in making the thicknesses uniform and making the surface smooth. As the results, the friction between the wire and the wire passing internal face of the hole in a bonding tool is reduced, thereby ensuring excellent wire feeding performance. Furthermore, since the adhesiveness among the core, the different metal layer and the coating layer is high, it is possible to solve the problem of the peeled flakes of the coating layer and the different metal layer clogging inside the bonding tool.

As in the case of the embodiment disclosed in Japanese Laid-open Patent Publication No. 62-97360, the forming methods by the chemical and physical vapor deposition methods are high in production cost in many cases. However, when a thin film, such as the different metal layer, is formed, the cost of the production becomes lower to an allowable level in some cases. Hence, the formation of the different metal layer by the chemical and physical vapor deposition methods can be taken into consideration.

In the process for producing a bonding wire having no different metal layer, the copper of the core material dissolves in the plating liquid during the formation of the coating layer by electroplating as described above, whereby the plating solution deteriorates. However, in the case when the wire has a different metal layer, plating is not carried out on the copper but on the different metal layer. Hence, the deterioration of the plating solution owing to the dissolution of the copper does not occur. The plating is thus carried out preferably.

Hereinafter, embodiments of the present invention will be described below by Example. The Example does not limit the scope of the present invention.

### EXAMPLE

A copper wire having a purity of 99.995% and an diameter of 200 μm was subjected to electroplating in order to form a gold strike plating having a thickness of about 0.01 μm and then a palladium plating having a thickness of about 0.8 μm. By drawing this wire, a copper bonding wire composed of a copper core having a diameter of 25 μm, a palladium layer (coating layer) having a thickness of 0.1 μm and a gold layer (different metal layer) having a thickness of 0.001 μm was produced. By using this wire, balls having various diameters were formed by a bonder (Model FB137 produced by KAIJO Corporation), and the fraction defective of the shape and major defective shapes at that time was examined. The diameter of each ball was defined as the diameter of a true sphere formed in accordance with conditions in which the balls were formed. As the ball formation conditions, the distance between the tip of the wire and the spark rod was set at 400 μm, and nitrogen was sprayed to the tip of the wire at a flow rate of 1 litter/minute to reduce the concentration of the oxygen around the tip. The results are shown in Table 1.

### Comparison Example 1

By using a bonding wire having the same structure as that of the above Example except that no gold layer (different metal layer) was formed, balls were formed in the same conditions as described above. The fraction defective of the shape and major defective shapes was examined, just as in the case of the Example. The results are shown in Table 1.

### Comparison Example 2

A copper wire having a purity of 99.995% and an diameter of 200 μm was subjected to electroplating in order to form a gold plating having a thickness of about 0.8 μm. By drawing this wire, a copper bonding wire composed of a copper core having a diameter of 25 μm, and a gold layer having a thickness of 0.1 μm was produced. The fraction defective of the shape and major defective shapes was examined, just as in the case of the Example. The results are shown in Table 1.

As shown in Table 1, the bonding wire of Example having a gold strike plating layer (different metal layer) exhibits a superior ball formation characteristic to the bonding wires of Comparative examples.

TABLE 1

| | | Comparative | Comparative |
|---|---|---|---|
| | Example | example 1 | example 2 |
| Coating layer | palladium | palladium | gold |
| Different | Gold | none | none |
| metal layer | | | |
| Diameter of | | | |
| ball | | | |
| 40 μm | 0/50 | 0/50 | 49/50 (*2) |
| 50 μm | 0/50 | 0/50 | 48/50 (*2) |
| 60 μm | 0/50 | 0/50 | 45/50 (*2) |
| 70 μm | 1/50 (*1) | 5/50 (*1) | 30/50 (*2) |
| 80 μm | 7/50 (*1) | 15/50 (*1) | 0/50 |

(*1) indicate the defect of the shape of a golf-club, and
(*2) indicate the defect of the shape of a spear.

In Table 1, the denominator indicates number of the test samples, and the numerator indicates number of the defect.

Industrial Applicability

The bonding wire of the present invention has an excellent ball formation capability, whereby balls having a shape of a true sphere can be formed in a wide ball diameter range. In other words, the bonding wire is excellent in bonding reliability. In addition, in the case when the coating layer is formed by plating, the plating solution used in the plating process does not deteriorate, thereby being advantageous. Hence, the bonding wire is low in production cost. Furthermore, since the adhesiveness of the coating layer is high, the bonding wire is also excellent in bonding reliability from this point of view.

Moreover, since copper having stiffness is used as the core material, bonded wires are hardly drifted by the flow of resin during resin encapsulation, whereby there is a low possibility that adjacent wires make contact with each other.

The bonding wire of the present invention is used, for example, for connecting electrodes on integrated circuit chips and conductive wires on circuit wiring substrates, as an inexpensive bonding wire having excellent characteristics.

The integrated circuit device using the bonding wire is inexpensive and excellent in reliability, and can be used in various uses.

1. A bonding wire comprising a core mainly consisting of copper, a different metal layer formed of a metal other than copper and formed on the core, and a coating layer formed of an oxidation-resistant metal having a melting point higher than that of copper and formed on the different metal layer.

2. The bonding wire according to claim 1, wherein the metal forming the different metal layer is a metal selected from gold, platinum, palladium, rhenium, rhodium, ruthenium, titanium, magnesium, iron, aluminum, zirconium, chromium, nickel, silver, tin, zinc, osmium, iridium and alloys of these.

3. The bonding wire according to a claim 2, wherein the metal forming the different metal layer is a metal hardly or scarcely soluble in the plating solution for use in the formation of the coating layer.

4. The bonding wire according to claim 2, wherein the metal forming the different metal layer is a metal selected from gold, platinum, palladium, chromium, nickel, silver, tin, zinc and alloys of these.

5. The bonding wire according to claim 4, wherein the metal forming the different metal layer is gold, platinum or palladium.

6. The bonding wire according to claim 5, wherein the metal forming the different metal layer is gold.

7. The bonding wire according to claim 1, wherein the different metal layer is formed by electroplating.

8. The bonding wire according to claim 7, wherein the different metal layer is formed by strike plating.

9. The bonding wire according to claim 1, wherein the metal forming the coating layer is a metal having a melting point 200° C. higher than that of copper.

10. The bonding wire according to claim 9, wherein the metal forming the coating layer is a metal selected from palladium, platinum, nickel and alloys of these.

11. The bonding wire according to claim 1, wherein elongation per unit sectional area of the wire is 0.021%/μm² or more.

12. The bonding wire according to claim 1, wherein the thickness of the coating layer is a value satisfying the relationship of 0.007≦Y≦0.05, when it is assumed that Y=(the sectional area of the coating layer divided by the sectional area of the core) when the wire is cross-sectioned perpendicularly.

13. The bonding wire according to claim 1, wherein the coating layer is formed by electroplating.

14. An integrated circuit device using the bonding wire according to claim 1.
